(19) United States
(12) Patent Application Publication
(10) Pub. No.: US 2013/0133732 A1
(43) Pub. Date: May 30, 2013

(54) METHOD FOR FORMING INTERCONNECT IN SOLAR CELL

(71) Applicants: Hsuan-Sheng YANG, Taichung City (TW); Wen-Chin LEE, Baoshan Township (TW)

(72) Inventors: Hsuan-Sheng YANG, Taichung City (TW); Wen-Chin LEE, Baoshan Township (TW)

(73) Assignee: Taiwan Semiconductor Manufacturing Co., Ltd., Hsin-Chu (TW)

(21) Appl. No.: 13/307,025

(22) Filed: Nov. 30, 2011

(51) Int. Cl. H01L 31/0224; H01L 31/18

(52) U.S. Cl. 136/256; 438/98; 257/E31.126

(57) ABSTRACT

A thin film solar cell and process for forming the same. The solar cell includes a bottom electrode, semiconductor light absorbing layer, and top electrode. Interconnects may be formed between the top and bottom electrodes by electrochemical plating of conductive materials in recessed regions formed between the electrodes. In some embodiments, the conductive materials may be optically opaque metals having non-light transmissive properties. The interconnects are highly conductive and minimize the thickness of the top electrode layer, thereby enhancing light transmission and cell energy conversion performance.

### FIELD

The present invention generally relates to photovoltaic solar cells, and more particularly to thin film solar cells and methods for forming same.

### BACKGROUND

Thin film photovoltaic (PV) solar cells are one class of energy source devices which harness a renewable source of energy in the form of light that is converted into useful electrical energy which may be used for numerous applications. Thin film solar cells are multi-layered semiconductor structures formed by depositing various thin layers and films of semiconductor and other materials on a substrate. These solar cells may be made into light-weight flexible sheets in some forms comprised of a plurality of individual electrically interconnected cells. The attributes of light weight and flexibility gives thin film solar cells broad potential applicability as an electric power source for use in portable electronics, aerospace, and residential and commercial buildings where they can be incorporated into various architectural features such as roof shingles, facades, and skylights.

Thin film solar cell semiconductor packages generally include an electrically conductive bottom electrode (also referred to as a back contact) formed on a substrate and a light-transmissive electrically conductive top electrode (also referred to as a top contact) formed above the bottom electrode. Top electrode films have been made for example of light transmissive transparent conductive oxide (“TCO”) materials, which are essentially transparent to light and pass light incident on the TCO through to semiconductor layers formed beneath in the solar cell.

Deposited between the bottom electrode and top electrode is an active light absorber layer, which essentially captures and transforms light energy into electrical energy in well known manner. The absorber layer is made of a light-sensitive and radiation energy-sensitive material that is capable of converting incident light energy into electrical energy in well known fashion. A conductive interconnect is formed in the solar cell to electrically couple the TCO top electrode layer with the bottom electrode layer below through the absorber layer. Heretofore, the interconnect has been formed by forming a vertical recess through the absorber layer such as by scribing prior to depositing the TCO electrode layer. This exposes the bottom electrode within the interconnect recesses. The TCO material is then deposited on the absorber layer in a typically single process step, generally covering the entire surface of the absorber layer with TCO including at least partially or completely filling the interconnect recess including along the vertical side walls. The TCO material itself therefore creates the conductive interconnect through the recess to the bottom electrode layer.

An improved interconnect for a thin film solar cell is desired.

### BRIEF DESCRIPTION OF THE DRAWINGS

The features of the exemplary embodiments will be described with reference to the following drawings where like elements are labeled similarly, and in which:

FIGS. 1-4 show cross-sections of a solar cell during sequential steps in an exemplary process for forming a solar cell and interconnect according to one embodiment of the present disclosure, in which the interconnect formed fully fills the interconnect recess;

FIGS. 5-6 show cross-sections of a solar cell during alternative sequential steps in the exemplary process of FIGS. 1-4, in which the interconnect formed partially fills the interconnect recess; and

FIG. 7 is a flow chart showing the sequential steps in the exemplary processes of FIGS. 1-6.

All drawings are schematic and are not drawn to scale.

### DETAILED DESCRIPTION

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected,” refer to a relationship wherein structures are secured or attached to one another either directly or indirectly through intervening structures, as well as both movable or rigid attachments or relationships, unless expressly described otherwise. The term “adjacent” as used herein to describe the relationship between structures/components includes both direct contact between the respective structures/components referenced and the presence of other intervening structures/components between respective structures/components. Moreover, the features and benefits of the disclosure are illustrated by reference to the exemplary embodiments. Accordingly, the disclosure expressly should not be limited to such exemplary embodiments illustrating some possible non-limiting combination of features that may exist alone or in other combinations of features.

FIG. 4 illustrates an exemplary embodiment of a thin film solar cell having a highly conductive interconnect structure that may be made by an exemplary method disclosed herein. Solar cell 100 generally includes a substrate 110, a bottom electrode layer 120 formed thereon, an absorber layer 130 formed thereon, a buffer layer 140 formed thereon, and a TCO top electrode layer 150 formed thereon. In some embodiments, the buffer layer 140 may be omitted wherein the TCO is deposited directly on the absorber layer 130.

Use of TCO alone for forming the interconnect may not be completely ideal in all instances. In order to have good sidewall coverage of TCO in the interconnect recess, the thickness of the TCO coating on top of the absorber layer (which simultaneously deposits in the recess as well) cannot be too thin. Otherwise high electrical resistance occurs caused by too thin of a layer of TCO on the interconnect sidewalls. This decreases the overall energy conversion performance and efficiency of the solar cell.

Conversely, depositing a thick layer of TCO on the absorber layer to avoid the foregoing problems of a too thin layer of TCO on the interconnect recess sidewalls and corresponding high resistance may cause lower light transmission through the TCO to the active light absorber layer below. Low light transmission through the TCO similarly decreases the overall energy conversion performance and efficiency of the solar cell.

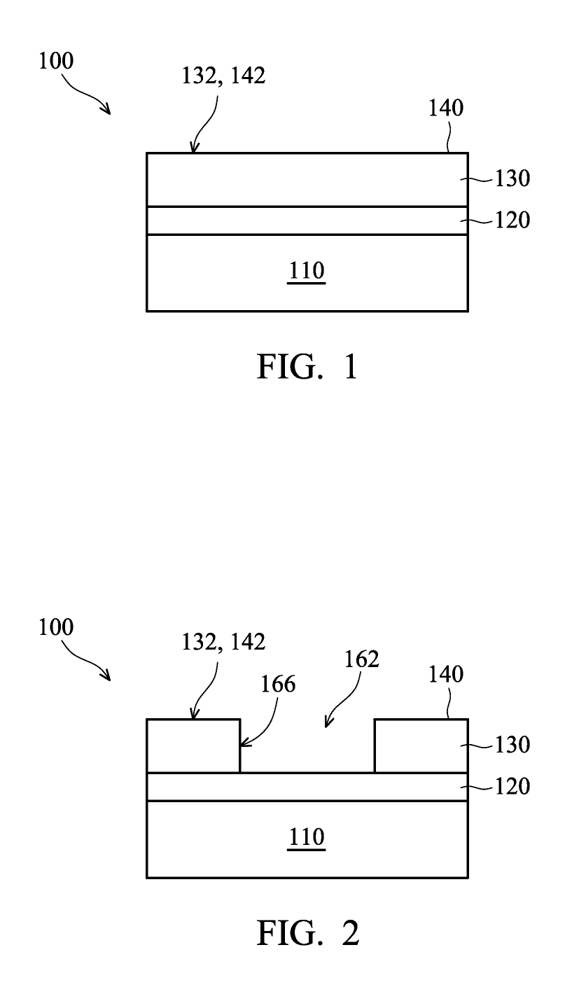

In one embodiment according to the present disclosure, a conductive interconnect 160 is formed between top electrode layer 150 and bottom electrode layer 140. Interconnect 160 extends vertically through the solar cell 100 package. In one embodiment, interconnect 160 may be formed of a separate and different conductive material than the TCO top electrode layer 150 as further described herein. In some embodiments, interconnect 160 may be made of a conductive metal. In the embodiment shown in FIG. 1, the interconnect 160 material may completely fill the interconnect recess 162 formed through the absorber layer 130 such that the interconnect has an upper surface 164 that is substantially planar and level or coextensive with the upper surface 132 defined by either the absorber layer 130 or upper surface 142 defined by buffer layer 140 if optionally provided. In another possible embodiment shown in FIG. 6, the interconnect 160 may partially fill interconnect recess 162.

Solar cells further generally include micro-channels which are patterned and scribed into the semiconductor structure to interconnect the various conductive material layers and to separate adjacent cells. These micro-channels or “scribe lines” as commonly referred to in the art are given “P” designations related to their function and step during the semiconductor solar cell fabrication process. The P1 and P3 scribe lines are essentially for cell isolation. P2 scribe line forms interconnections. P1 scribe lines interconnect the absorber layer to the substrate and pattern the TCO panel into individual cells. P2 scribe lines remove absorber material to interconnect the top TCO electrode to the bottom electrode thereby preventing the intermediate buffer layer from acting as a barrier between the top and bottom electrodes. P3 scribe lines extend completely through the TCO, buffer layer, and absorber layer to the bottom electrode or substrate to isolate each cell defined by the P1 and P2 scribe lines.

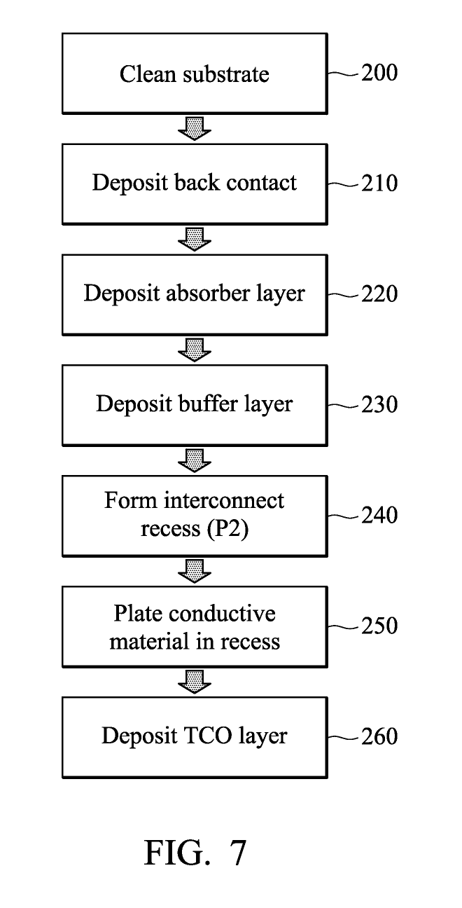

An exemplary embodiment of a method for forming solar cell 100 shown in FIG. 4 will now be described. FIG. 7 shows the basic method steps in the forming process.

Referring now to FIGS. 1 and 7, substrate 110 is first cleaned (step 200) by any suitable conventional means used in the art to prepare the substrate for receiving the bottom electrode layer.

Suitable conventional materials that may be used for substrate 110 include without limitation glass such as for example without limitation soda lime glass, ceramic, metals such as for example without limitation thin sheets of stainless steel and aluminum, or polymers such as for example without limitation polyamides, polyethylene terephthalates, polyethylene naphthalates, polymeric hydrocarbons, cellulosic polymers, polycarbonates, polyethers, and others. In one exemplary embodiment, glass may be used for substrate 110.

Next, bottom electrode layer 120 is then formed on a substrate 110 (step 210) by any conventional method commonly used in the art including without limitation sputtering, atomic layer deposition (ALD), chemical vapor deposition (CVD), or other techniques.

In one embodiment, bottom electrode layer 120 may be made of molybdenum (Mo); however, other suitable electrically conductive metallic and semiconductor materials conventionally used in the art may be used such as Al, Ag, Sn, Ti, Ni, stainless steel, ZnTe, etc.

In some representative embodiments, without limitation, bottom electrode layer 120 may preferably have a thickness ranging from about and including 0.1 to more 2 microns (μm). In one embodiment, layer 120 has a representative thickness on the order of about 0.5 μm.

A semiconductor light absorber layer 130 is next formed on top of bottom electrode layer 120 (step 220), as shown in FIG. 1.

In one embodiment, absorber layer 130 may be a p-type doped chalcogenide material commonly used in the art, and preferably without limitation CIGS Cu(In,Ga)Se₂ in some possible embodiments. Other suitable chalcogenide materials may be used including without limitation Cu(In,Ga)(Se, S)₂ or “CIGSS,” CuInSe₂, CuGaSe₂, CuInS₂, and Cu(In,Ga)S₂.

Suitable p-type dopants that may commonly be used for forming absorber layer 130 include without limitation boron (B) or other elements of group II or III of the periodic table.

Absorber layer 130 formed of CIGS may be formed by any suitable vacuum or non-vacuum process conventionally used in the art. Such processes include, without limitation, selenization, evaporation, sputtering, chemical vapor deposition, etc.

In some representative embodiments, without limitation, absorber layer 130 may preferably have a thickness ranging from about and including 0.5 to 3 microns (μm). In one embodiment, absorber layer 130 has a representative thickness on the order of about 2 μm.

With continuing reference to FIGS. 1 and 7, an n-type thin buffer film or layer 140 may optionally then be formed on absorber layer 130 (step 230) to create an electrically active n-p junction. In one embodiment, buffer layer 130 may be CdS. Buffer layer 140 may be formed any suitable method commonly used in the art. In one embodiment, buffer layer 140 may be formed by a conventional electrolyte chemical bath deposition (CBD) process commonly used in the art for forming such layers using an electrolyte solution that contains sulfur. In some representative embodiments, without limitation, buffer layer 140 may preferably have a thickness ranging from about and including 0 to 0.1 microns (μm). In one embodiment, buffer layer 140 has a representative thickness on the order of about 0.02 μm.

After forming CdS buffer layer 140 if provided, or forming absorber layer 130 if no buffer layer is provided, the P2 scribe lines are next cut through the absorber layer 130 to expose the top uppermost surface of the bottom electrode layer 120 within the open scribe line or channel (step 240, FIG. 7). This step also forms interconnect recesses 162 having vertical sidewalls 166 with an open top and an open bottom revealing the bottom electrode layer 120 therein. Any suitable method conventionally used in the art may be used to cut the P2 scribe lines forming interconnect recesses 162, including without limitation mechanical (e.g. cutting stylus) or laser scribing. The solar cell 100 semiconductor package formed thus far with interconnect recess 162 is shown in FIG. 2.

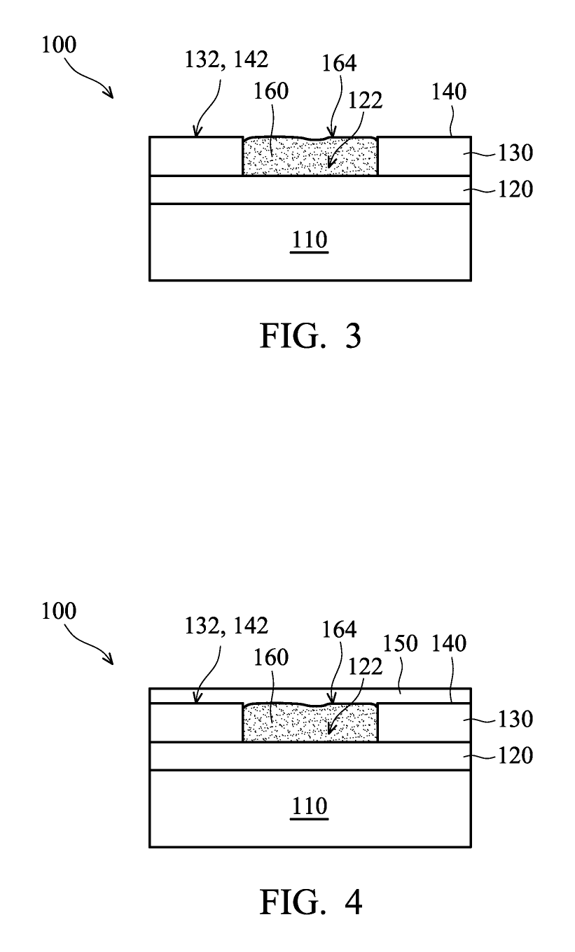

Before depositing the TCO material on partially formed solar cell 100 to form the top electrode layer, the conductive interconnect 160 is next made as shown in FIG. 3. In one embodiment, an electrochemical deposition (ECD) plating process is used to deposit conductive material within interconnect recesses 162 for forming interconnect 160 (step 250, FIG. 7). ECD is a wet chemistry process used to gradually build the conductive interconnects and uses an electrolytic solution containing the primary conductive material and other additives. The ECD plating process is performed to gradually and successively build up the interconnect 160 within recesses 162. The conductive interconnect material is deposited onto exposed bottom electrode layer 120 within the recesses 162 and gradually fills the recesses vertically from the bottom up. The conductive interconnect material horizontally or laterally fills the interconnect recess from sidewall 166 to opposing sidewall to eliminate or minimize thin regions of conductive material along the sidewalls that might cause unwanted high resistance which degrades solar cell performance.

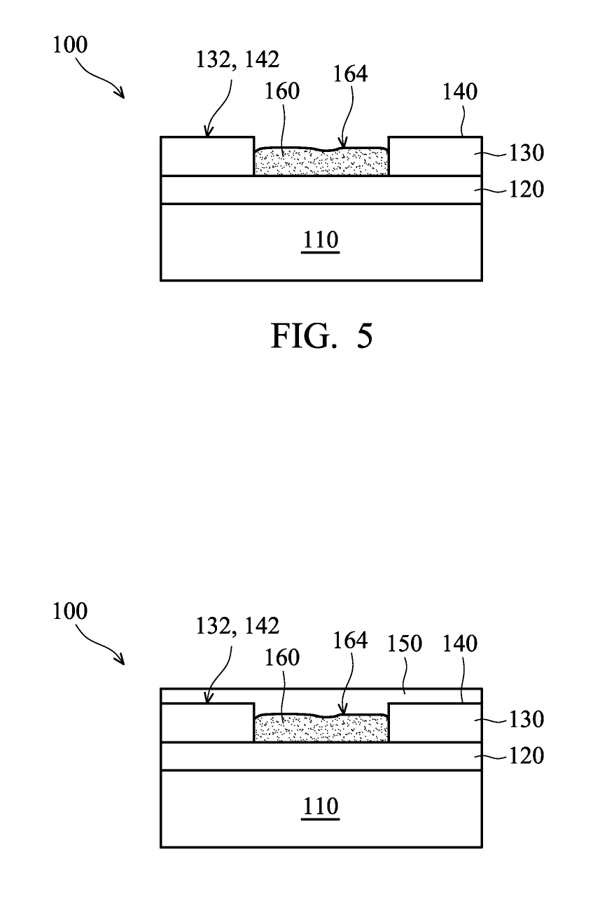

In some embodiments, the conductive material for interconnect 160 may be successively built up vertically within interconnect recesses 162 by the ECD plating process until the material substantially fills recesses 162 and the top surface 164 of the interconnect is essentially level or planar with the top surface 132 of absorber layer 130 (except for possible minor interconnect top surface imperfections or variations) as shown in FIG. 4. In other embodiment, the conductive material may be successively built up and at least partially fill interconnect recess 162 as shown in FIG. 5, ultimately resulting in the solar cell 100 shown in FIG. 6. It is desired that the conductive interconnect material fill recess 162 to the greatest extent possible to minimize the amount of TCO material that will be in contact with the sidewalls 166 of the absorber layer within the recess when the TCO layer is later formed. Process limitations in the ECD plating method and machine used to perform the plating may prevent the recesses 162 from becoming totally filled and some shrinkage may occur after the plating process is completed.

The conductive material plated on the absorber layer 130 and bottom electrode layer 120 within recess 162 of solar cell 100 to form interconnect 160 in one embodiment is a distinct and different type material than the light-transmissive electrically conductive TCO material used for forming top electrode layer 150. Accordingly, the conductive material for interconnect 160 may be a non-oxide and non-light-transmissive conductive material instead of the light-transmissive TCO material used for the top electrode and is formed in a separate process step from depositing the TCO on absorber layer 130. The interconnect 160 conductive material may be opaque to light in some embodiments since the interconnect is formed directly onto the bottom electrode layer 120 and confined to within interconnect recesses 162 which will not interfere with light transmission to the active absorber layer 130.

The conductive materials that may be used for interconnect 160 may include optically opaque materials and metals in some embodiments. Suitable metallic materials that may be used for interconnect 160 include without limitation copper, nickel, gold, silver, palladium, platinum, and alloys or combinations of the foregoing metals with other elements. In one exemplary embodiment, copper may be used.

A surface selective electrochemical plating process using organic additions may be used to form interconnects 160. Such a process will specifically target and deposit the conductive material preferentially within the regions of the interconnect recesses 162 directly onto the exposed uppermost top surface 122 of bottom electrode layer 120 (see FIGS. 2 and 3). The surface selective process minimizes or eliminates collateral and unwanted plating of the metal conductive material on the remaining regions such as the exposed horizontal top surface 132 of absorber layer 130, which would interfere with the transmission of light to layer 130 and degrade solar cell performance. The conductive material will therefore surface selectively be deposited and form within recesses 162 on top of the bottom electrode material. Advantageously, the interconnect forming and selective ECD plating process disclosed herein does not require masking to protect the absorber layer top surface 132 from plating with the conductive interconnect material. Suitable electrochemical plating bath include without limitation acid or alkaline metal ion solution. In one exemplary embodiment, copper sulfate electrochemical plating bath with heterocyclic nitrogen compound may be used.

The electrochemical plating process for forming interconnects 160 may be performed in any suitable commercially-available ECD plating machine operable for this purpose, such as for example the Sabre Systems available from Novellus Systems, Inc. of San Jose, Calif.; Raider-S ECD from Applied Materials, Inc. of Santa Clara, Calif., and others. In the present exemplary fabrication process, the partially completed solar cell 100 shown in FIG. 2 is first loaded into and mounted in the ECD plating machine. The interconnects 160 are then formed in the manner just described above. The solar cell 100 with finished interconnects 160 may then be removed from the ECD plating machine to complete the remaining fabrication steps such as top electrode layer 150 deposition and other steps.

In some embodiments, if there is some carryover and plating of conductive interconnect material onto regions of the absorber layer outside of interconnect recesses 162 such as on top surface 132, a conventional plasma etch process may then be optionally used (between steps 250 and 260 in FIG. 7) before depositing the TCO top electrode layer 150 to first remove unwanted thin films of conductive material from the absorber layer.

Referring now to FIG. 4, after forming the conductive interconnects 160, an n-type doped light transmissive top electrode layer 150 is next formed on top of absorber layer 130 or buffer layer 140 if used (step 260, FIG. 7) for collecting current (electrons) from the cell while absorbing a minimal amount of light which passes through to the light absorbing layer 130. Top electrode layer 150 may be made of an oxide material in some embodiments such as a TCO material. In one embodiment, the deposited TCO material may be bulk deposited to completely cover the entire upper surface of solar cell 100 shown in FIG. 3 including the exposed top horizontal surface 132 of absorber layer 130 and the upper or top exposed surfaces 164 of the conductive interconnects 160 formed therein, as shown in FIG. 4. The TCO top electrode layer 150 is electrically connected to bottom electrode layer 120 via the separate conductive interconnects 160 previously formed before the present process step, in lieu of using the TCO itself to form the interconnect as in some past solar cell packages. Advantageously, this produces a more highly conductive interconnects since the materials that may be used for forming interconnects 160 may be non-oxide, non-light transmissive and therefore high quality electrical conductors. The TCO top electrode layer 150, in embodiments described herein, may therefore be a film having a substantially uniform thickness (measured vertically) across the entire solar cell 100 with substantially flat opposing top and bottom regions as shown in FIG. 4.

Aluminum is one possible n-type dopant that is commonly used for TCO top electrodes in thin film solar cells; however, others suitable conventional dopants may be used such as without limitation phosphorus (P), arsenic (As) or other elements of group V or VI of the periodic table.

In one embodiment, the TCO used for top electrode layer 150 may be any conventional material commonly used in the art for thin film solar cells. Suitable TCOs that may be used include without limitation zinc oxide (ZnO), fluorine tin oxide (“FTO” or SnO₂:F), indium tin oxide (“ITO”), indium zinc oxide (“IZO” or In2O3/SnO2), indium oxide (In2O3), antimony tin oxide (ATO), tin oxide (SnO2), a carbon nanotube layer, or any other suitable coating materials possessing the desired properties for a top electrode. In one exemplary embodiment, the TCO used is ZnO.

In some possible embodiments where top electrode layer 150 may be made of ZnO, it should be noted that a thin intrinsic ZnO film (not shown) may sometimes form on top of absorber layer 130 during formation of the thicker n-type doped TCO top electrode layer 150.

It will be appreciated that since a different and separate conductive material other than TCO forms the interconnect 160, the thickness of TCO layer (measured vertically) can be minimized to only that thickness necessary to provide a good quality top electrode layer 150. The TCO layer receives incident light on its uppermost surface and transmits that light to the active absorber layer below. Advantageously, a thin TCO layer maximizes light transmission to the underlying absorber layer. In one embodiment, a thin TCO top electrode layer 150 may be depositing having a maximum thickness of 0.5 microns or less. This TCO thickness has been estimated to increase light transmission from about 80% to about 90%, thereby improving solar cell performance and energy conversion efficiency.

Additional conventional back end of line processes and lamination may be performed following formation of the thin film solar cell structure disclosed herein, as will be well known and understood by those skilled in the art. This may include laminating a top cover glass onto the cell structure with a suitable encapsulant therebetween such as without limitation a combination of EVA (ethylene vinyl acetate) and butyl to seal the cell. The EVA and butyl encapsulant is conventionally used in the art and may be applied directly onto the TCO top electrode layer 150 in the present embodiment, followed by applying the top cover glass thereon.

Suitable further back end processes may then be completed which may include forming front conductive grid contacts and one or more anti-reflective coatings (not shown) in a conventional manner well known in the art. The grid contacts will protrude upwards through and beyond the top surface of any anti-reflective coatings for connection to external circuits. The solar cell fabrication process produces a finished and complete thin film solar cell module.

According to the present disclosure, one exemplary method for forming interconnects in a thin film solar cell includes: forming a conductive bottom electrode layer on a substrate; forming an absorber layer on the bottom electrode layer; forming an open interconnect recess in the absorber layer, the recess extending through the absorber layer to the bottom electrode layer; depositing a metallic conductive material in the recess using an electroplating process, the electroplated recess defining an interconnect; and forming a light transmissive top electrode layer above the absorber layer, the top electrode layer being made of a material different than the interconnect. In some embodiments the top electrode is made of a transparent conductive oxide material and the interconnect is made of an optically opaque metal.

According to the present disclosure, another exemplary method for forming interconnects in a thin film solar cell includes: forming a conductive bottom electrode layer on a substrate; forming an absorber layer on the bottom electrode layer; scribing an open P2 scribe line through the absorber layer, the scribe line defining an interconnect recess extending through the absorber layer and exposing the bottom electrode layer therein; filling at least partially the interconnect recess with a metallic conductive material deposited directly onto the exposed bottom electrode layer, the metallic conductor defining an interconnect; and forming a top electrode layer above the absorber layer, the top electrode layer being made of a different conductive material than the interconnect. In one embodiment, the filling step is performed by electrochemical deposition plating. Therefore, the method may further include in some embodiments a step of positioning and mounting the solar cell in an electrochemical deposition plating machine prior to the filling step. In one embodiment, the interconnect is made of a plating material selected from the group consisting of copper, nickel, gold, silver, palladium, platinum, and alloys thereof.

According to the present disclosure, one exemplary thin film solar cell includes a bottom electrode layer formed on a substrate, a semiconductor absorber layer formed on the bottom electrode layer, and a top electrode layer formed above the absorber layer; the top electrode layer being formed of a light transmissive electrically conductive material. the solar cell further includes a conductive interconnect extending vertically through the absorber layer and electrically connecting the top electrode layer to the bottom electrode layer. The interconnect may be made of a conductive material different than the top electrode layer conductive material and is a separate and discrete structure from the top electrode. In some embodiments, the conductive material is an optically opaque, non-light-transmissive metal. In one embodiment, the top electrode layer is made of a transparent conductive oxide material.

While the foregoing description and drawings represent exemplary embodiments of the present disclosure, it will be understood that various additions, modifications and substitutions may be made therein without departing from the spirit and scope and range of equivalents of the accompanying claims. In particular, it will be clear to those skilled in the art that the present disclosure may be embodied in other forms, structures, arrangements, proportions, sizes, and with other elements, materials, and components, without departing from the spirit or essential characteristics thereof. One skilled in the art will further appreciate that the disclosure may be used with many modifications of structure, arrangement, proportions, sizes, materials, and components and otherwise, used in the practice of the disclosure, which are particularly adapted to specific environments and operative requirements without departing from the principles of the present disclosure. In addition, numerous variations in the exemplary methods and processes described herein may be made without departing from the spirit of the disclosure. The presently disclosed embodiments are therefore to be considered in all respects as illustrative and not restrictive, the scope of the disclosure being defined by the appended claims and equivalents thereof, and not limited to the foregoing description or embodiments. Rather, the appended claims should be construed broadly, to include other variants and embodiments of the disclosure, which may be made by those skilled in the art without departing from the scope and range of equivalents of the embodiments disclosed herein.

What is claimed is:

1. A method for forming interconnects in a thin film solar cell, the method comprising:
forming a conductive bottom electrode layer on a substrate;
forming an absorber layer on the bottom electrode layer;
forming an open interconnect recess in the absorber layer, the recess extending through the absorber layer to the bottom electrode layer;
depositing a metallic conductive material in the recess using an electroplating process, the electroplated recess defining an interconnect; and
forming a light transmissive top electrode layer above the absorber layer, the top electrode layer being made of a material different than the interconnect.

2. The method of claim 1, wherein the interconnect is made of a plating material selected from the group consisting of copper, nickel, gold, silver, palladium, platinum, and alloys thereof.

3. The method of claim 1, further comprising:
forming a buffer layer on the absorber layer before forming the interconnect recess, wherein the recess is formed through the buffer layer and absorber layer.

4. A thin film solar cell comprising:
a bottom electrode layer formed on a substrate;
a semiconductor absorber layer formed on the bottom electrode layer;
a top electrode layer formed above the absorber layer, the top electrode layer being formed of a light transmissive electrically conductive material; and
a conductive interconnect extending vertically through the absorber layer and electrically connecting the top electrode layer to the bottom electrode layer, the interconnect being made of a conductive metal or metal alloy different than the top electrode layer.

5. The solar cell of claim 4, wherein the interconnect is made of a non-light transmissive opaque material.

6. The solar cell of claim 5, wherein the top electrode layer is made of a transparent conductive oxide material.

7. The solar cell of claim 4, further comprising a buffer layer formed between the absorber layer and the top electrode layer.

8. The solar cell of claim 7, wherein the buffer layer is made of CdS.

9. The solar cell of claim 4, wherein the conductive interconnect material at least partially fills a recess formed between the top and bottom electrode layers.

10. The solar cell of claim 4, wherein the top electrode layer is formed an n-type material selected from the group consisting of zinc oxide, fluorine tin oxide, indium tin oxide, indium zinc oxide, indium oxide, tin oxide, antimony tin oxide (ATO), and a carbon nanotube layer.

11. The solar cell of claim 4, wherein the absorber layer is comprised of p-type chalcogenide materials or CdTe.

12. The solar cell of claim 4, wherein the top electrode layer has a maximum thickness of 3 microns.

13. The solar cell of claim 4, wherein the interconnect has an upper surface that is substantially flush with the top surface of the absorber layer.

14. The solar cell of claim 4, wherein the top electrode layer does not extend below a top surface of the absorber layer adjacent to the intereconnect.

15. The solar cell of claim 4, wherein the interconnect is made of a non-oxide metal or metal alloy and the top electrode layer is made of a transparent conductive oxide material.

16. The solar cell of claim 4, wherein the interconnect conductive material is deposited in a recess extending between the top electrode layer and the bottom electrode layer.

17. A thin film solar cell comprising:
a bottom electrode layer formed on a substrate;
a semiconductor absorber layer formed on the bottom electrode layer;
a top electrode layer formed above the absorber layer, the top electrode layer being formed of a light transmissive electrically conductive material; and
a conductive interconnect extending vertically through the absorber layer and electrically connecting the top electrode layer to the bottom electrode layer, the interconnect being made of a conductive material different than the top electrode layer conductive material.

18. The solar cell of claim 17, wherein the interconnect is made of a non-light transmissive metallic material.

19. The solar cell of claim 18, wherein the top electrode layer is made of a transparent conductive oxide material.

20. The solar cell of claim 18, wherein the interconnect is made of a non-oxide metal or metal alloy material.
